(19) United States
(12) Patent Application Publication
(10) Pub. No.: US 2025/0386710 A1
(43) Pub. Date: Dec. 18, 2025

(54) DISPLAY DEVICE AND MANUFACTURING METHOD OF DISPLAY DEVICE

(71) Applicant: Samsung Display Co., LTD., Yongin-si (KR)

(72) Inventors: Yunyoung LEE, Yongin-si (KR); Byoung Jin JIN, Yongin-si (KR); Hoi Kwan LEE, Yongin-si (KR); Jun Yeub LEE, Yongin-si (KR)

(21) Appl. No.: 19/074,047

(22) Filed: Mar. 7, 2025

(30) Foreign Application Priority Data
Jun. 14, 2024 (KR) 10-2024-0077624

(51) Int. Cl. H10K 59/80; H10K 59/12; H10K 59/126; H10K 102/00

(52) U.S. Cl. CPC H10K 59/873; H10K 59/1201; H10K 59/126; H10K 59/8791; H10K 2102/351

(57) ABSTRACT

A display device is disclosed. The display device may include a display panel including a plurality of pixels, a polarizer on the display panel, a cover window on the polarizer, a light blocking film on a rear surface of the cover window, and an adhesive layer between the light blocking film and the polarizer, wherein the adhesive layer is only between the light blocking film and the polarizer that overlap each other.

### CROSS-REFERENCE TO RELATED APPLICATION

The present application claims priority to and the benefit of Korean Patent Application No. 10-2024-0077624, filed on Jun. 14, 2024, in the Korean Intellectual Property Office, the entire disclosure of which is incorporated herein by reference.

### BACKGROUND

### 1. Field

One or more embodiments of the present disclosure relate to a display device, a manufacturing method of the display device, and an electronic device including the display device.

### 2. Description of the Related Art

Display devices, such as liquid crystal displays (LCD), organic light emitting diode (OLED) displays, and/or the like, have a display panel including a plurality of pixels to display images and a cover window to protect the display panel. The cover window may have any suitable form to meet design requirements and/or to have impact resistance characteristics. For example, as the demand for thinner display panels is growing, the thickness of the cover window is also trending thinner, so research is being conducted on the shape of the cover window that may compensate for this trend.

### SUMMARY

One or more aspects of embodiments of the present disclosure are directed toward a display device and a manufacturing method of the display device that may improve or enhance the impact resistance characteristic of an edge portion of the cover window of the display device and improve or enhance the surface quality of the cover window.

One or more aspects of embodiments of the present disclosure are directed toward a display device and a manufacturing method of the display device that may prevent or reduce defects (e.g., a degree or occurrence of undesirable defects) in the polarizer that is included in the display device and defects (e.g., a degree or occurrence of undesirable defects) in the display device resulting therefrom.

One or more aspects of embodiments of the present disclosure are directed toward a display device and a manufacturing method of the display device that may prevent or reduce defects (e.g., a degree or occurrence of undesirable defects) in a light blocking portion of the edge of the display device.

Additional aspects of embodiments will be set forth in part in the description which follows and, in part, will be apparent from the description or may be learned by practice of the presented embodiments of the disclosure.

A display device according to one or more embodiments includes a display panel including a plurality of pixels, a polarizer on the display panel, a cover window on the polarizer, a light blocking film on a rear surface of the cover window, and an adhesive layer between the light blocking film and the polarizer, wherein the adhesive layer is only between the light blocking film and the polarizer that overlap each other.

The cover window may include a central portion that overlaps the polarizer, and an edge portion around the central portion, and a thickness of the central portion in a first direction may be greater than a thickness of the edge portion in the first direction.

The edge portion may include an area that overlaps the polarizer in the first direction and an area that does not overlap the polarizer in the first direction.

The light blocking film may be in contact with a rear surface of the edge portion and may not overlap the central portion in the first direction.

An inner side of the light blocking film may be in contact with a side of the central portion, an outer side of the light blocking film may be aligned with a side of the edge portion, and an inner side of the adhesive layer may be in contact with a side of the central portion.

A sum of a thickness of the adhesive layer, a thickness of the light blocking film, and a thickness of the edge portion in the first direction may be equal to a thickness of the central portion in the first direction.

The central portion may be in contact with the polarizer.

An edge of an upper surface of the edge portion may be chamfered to provide an inclined (e.g., substantially inclined) surface.

A display device according to one or more embodiments includes a display panel including a plurality of pixels, a polarizer on the display panel, a cover window on the polarizer, a light blocking film on a rear surface of the cover window, and an adhesive layer between the light blocking film and the polarizer, wherein the cover window includes a central portion that overlaps the polarizer, and an edge portion around the central portion, the central portion is in contact with the polarizer, the edge portion is not in contact with the polarizer, and the adhesive layer is between the edge portion and the polarizer.

A thickness of the central portion in the first direction may be greater than a thickness of the edge portion in the first direction.

The edge portion may include an area that overlaps the polarizer in a first direction and an area that does not overlap the polarizer in the first direction.

The light blocking film may be in contact with a rear surface of the edge portion and may not overlap the central portion in the first direction.

An inner side of the light blocking film may be in contact with a side of the central portion, an outer side of the light blocking film may be aligned with a side of the edge portion, and an inner side of the adhesive layer may be in contact with a side of the central portion.

A sum of a thickness of the adhesive layer, a thickness of the light blocking film, and a thickness of the edge portion in the first direction may be equal to a thickness of the central portion in the first direction.

An edge of an upper surface of the edge portion may be chamfered to provide an inclined (e.g., substantially inclined) surface.

A manufacturing method of a display device according to one or more embodiments includes preparing a mold having a first upper surface and a first inclined surface connected to the first upper surface; coating (e.g., applying) a material for a cover window on the mold to provide a first cover window having a second upper surface in contact with the first upper surface and a second inclined surface in contact with the first inclined surface, mounting a display panel and a polarizer joined to each other on a supporting portion of a jig including the supporting portion and the side portion; providing an adhesive layer in an edge area of the polarizer; attaching a light blocking film on and across an upper surface of the side portion of the jig and the adhesive layer; and bonding the polarizer and the light blocking film fixed to the jig on the first cover window to provide a second cover window including an edge portion in contact with the light blocking film and a central portion in contact with the polarizer.

A thickness of the central portion in a first direction may be greater than a thickness of the edge portion in the first direction.

The second cover window may have the second upper surface and the second inclined surface, and the method may further include curing the second cover window, removing the mold and the jig, and cutting the second cover window and the light blocking film along a cutting line that overlaps the second inclined surface.

The mold may further have a first edge upper surface that is connected to the first inclined surface and is parallel (e.g., substantially parallel) to the first upper surface, the first cover window may further have a second edge upper surface that is connected to the second inclined surface and is parallel (e.g., substantially parallel) to the second upper surface, and the inclined (e.g., substantially inclined) surface may be a flat (e.g., substantially flat) surface.

The mold may have a vertical (e.g., substantially vertical) surface that is connected to the first inclined surface and is vertical (e.g., substantially vertical) to the first upper surface, the first cover window may have a side that is connected to the second inclined surface and is perpendicular (e.g., substantially perpendicular) to the second upper surface, and a side of the light blocking film may be aligned with the side of the first cover window.

According to one or more embodiments, the impact resistance characteristics of the edge portion of the cover window of the display device may be improved or enhanced, and the surface quality of the cover window may be improved or enhanced. In one or more embodiments, defects (e.g., a degree or occurrence of undesirable defects) in the polarizer included in the display device and the resulting defects (e.g., a degree or occurrence of resulting undesirable defects) in the display device may be prevented or reduced. It may also prevent or reduce defects (e.g., a degree or occurrence of undesirable defects) in the light blocking portion of the edge of the display device.

According to one or more embodiments, an electronic device includes the display device.

The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The above and other aspects and features of certain embodiments of the present disclosure will be more apparent from the following description taken in conjunction with the accompanying drawings, in which:

FIG. 1 is an exploded perspective view of a display device according to one or more embodiments,

FIG. 2 is a cross-sectional view of a display device according to one or more embodiments,

FIG. 3 is a cross-sectional view of a part of an edge of a cover window of the display device as illustrated in FIG. 2,

FIG. 4 is a cross-sectional view of a master mold at one process step of a manufacturing method of a display device according to one or more embodiments,

FIG. 5 is a view illustrating an intermediate step to provide a mold by using a master mold in one process step of a manufacturing method of a display device according to one or more embodiments,

FIG. 6 is a view illustrating a step to process a mold in the intermediate step as illustrated in FIG. 5 in a vacuum chamber,

FIG. 7 is a view illustrating a step to cure a mold by heat treatment (e.g., heat curing) after the processing step as illustrated in FIG. 6,

FIG. 8 is a view illustrating a step to attach a mold to a substrate after the heat curing step as illustrated in FIG. 7,

FIG. 9 is a view illustrating a step to coat (e.g., to apply) a material for a cover window on the mold as illustrated in FIG. 8,

FIG. 10 is a view illustrating a step to mount a display panel, a polarizer, and a light blocking film on a jig according to one or more embodiments,

FIG. 11 is a perspective view of a state in which a polarizer and a light blocking film are mounted on a jig in the step as illustrated in FIG. 10,

FIG. 12 is a view illustrating a combination of the jig as illustrated in FIG. 10 and FIG. 11 on a material for a cover window in the step as illustrated in FIG. 9,

FIG. 13 is a view illustrating a step to cure a material for a cover window after the step as illustrated in FIG. 12,

FIG. 14 is a view illustrating a step to remove a mold and a jig after the step as illustrated in FIG. 13,

FIG. 15 is a view illustrating a step to cut a cover window,

FIG. 16 is a top plan view of a cover window cut in the step as illustrated in FIG. 15,

FIG. 17 is a view illustrating a combination of a jig in which a display panel, a polarizer, and a light blocking film are mounted on a material for a cover window coated on a mold in one process step of a manufacturing method of a display device according to one or more embodiments,

FIG. 18 is a view illustrating a combination of a jig in which a display panel, a polarizer, and a light blocking film are mounted on a material for a cover window coated on a mold in one process step of a manufacturing method of a display device according to one or more embodiments, and

FIG. 19 is a cross-sectional view of a display device according to one or more embodiments.

### DETAILED DESCRIPTION

The subject matter of the present disclosure will be described in more detail hereinafter with reference to the accompanying drawings, in which exemplary embodiments of the present disclosure are illustrated. As those skilled in the art would realize, the described embodiments may be modified in one or more different ways, all without departing from the spirit or scope of the present disclosure.

The drawings and description are to be regarded as illustrative in nature and not restrictive, and like reference numerals designate like elements throughout the specification.

Further, in the drawings, the size and thickness of each element may be randomly represented for better understanding and ease of description, but embodiments of the present disclosure are not limited thereto. In the drawings, the thickness of layers, films, panels, areas, and/or the like may be exaggerated for clarity. In the drawings, for better understanding and ease of description, the thicknesses of some layers and areas may be exaggerated.

The singular forms “a,” “an,” and “the” as used herein are intended to include the plural forms as well unless the context clearly indicates otherwise.

It should be understood that if (e.g., when) an element, such as a layer, a film, an area, or a substrate, is referred to as being “on” another element, it may be directly on the other element or intervening elements may also be present. In contrast, if (e.g., when) an element is referred to as being “directly on” another element, there are no intervening elements present. Further, in the specification, the word “on” or “above” refers to being positioned (or provided or arranged) on or below the object portion, and does not necessarily refer to being positioned (or provided or arranged) on the upper side of the object portion based on a gravitational direction.

In one or more embodiments, unless explicitly stated to the contrary, the word “include” or “have” and variations thereof, such as “includes,” “including,” “has,” or “having,” should be understood to imply the inclusion of stated elements but not the exclusion of any other elements.

Further, throughout the specification, the phrase “in a plan view” refers to viewing a target portion from the top, and the phrase “in a cross-section” refers to viewing a cross-section provided by vertically (e.g., substantially vertically) cutting a target portion from the side.

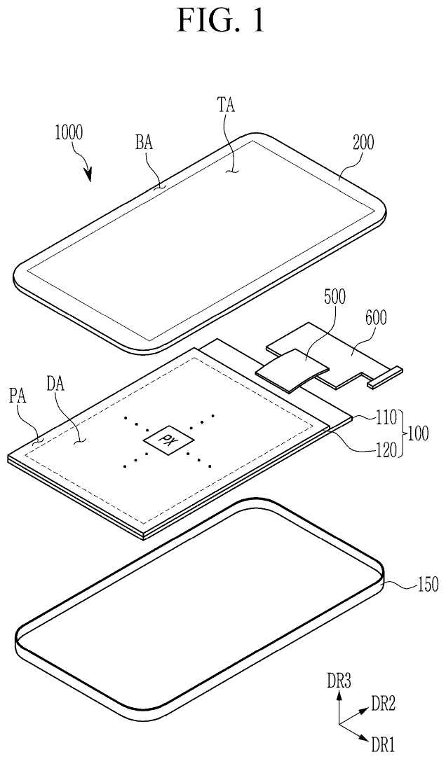

A display device according to one or more embodiments is described with reference to FIG. 1.

FIG. 1 is an exploded perspective view of a display device according to one or more embodiments.

FIG. 1 is a portable terminal as an example of a display device 1000 according to one or more embodiments, but is not limited thereto. The portable terminal may be one or more suitable display devices, such as a tablet PC, a smart phone, a personal digital assistant (PDA), a portable multimedia player (PMP), a game console, and/or a wristwatch-type or -kind electronic device. However, the display device 1000 according to one or more embodiments is not limited thereto. The display device may be large electron equipment, such as a television and/or an external billboard as well as small electron equipment, such as a personal computer, a laptop computer, a car navigation unit, and/or a camera.

Referring to FIG. 1, the display device 1000 according to one or more embodiments may include a display panel 100, a cover window 200, and a case member 150.

The display panel 100 may include a display area DA, which is an area to display images, and a peripheral area PA around the display area DA. The display area DA may include a plurality of pixels PX, which are the units to display an image. The peripheral area PA may be an area that does not display images.

The display panel 100 may be a display panel of one or more suitable display devices, such as a liquid crystal display and/or an organic light emitting display device.

The display panel 100 may include a substrate 110 and an encapsulation portion 120. A plurality of signal lines, a plurality of transistors, and a plurality of pixel electrodes may be between the substrate 110 and the encapsulation portion 120. The pixel electrodes may be electrically connected to at least one transistor.

For example, if (e.g., when) the display panel 100 is a display panel of an emissive display device, a plurality of light emitting elements may be between the substrate 110 and the encapsulation portion 120. The light emitting element may include a pixel electrode, a common electrode, and at least one light emitting layer between the pixel electrode and the common electrode. The light emitting layer may be an organic emission layer including an organic light emitting material, an inorganic light emitting layer including an inorganic light emitting material, and/or a light emitting layer including quantum dots, which may be semiconductor nanocrystals.

One pixel electrode may be in each pixel PX, but embodiments of the present disclosure are not limited thereto.

The encapsulation portion 120 may be a substrate and may include a plurality of insulating (e.g., electrically insulating) layers. For example, the encapsulation portion 120 may include at least one inorganic insulating (e.g., electrically insulating) layer and/or at least one organic insulator (e.g., electrical insulator). For example, the encapsulation portion 120 may include alternately stacked inorganic insulating (e.g., electrically insulating) layers and organic insulators (e.g., electrical insulators). The encapsulation portion 120 may protect the light emitting element by sealing it from the outside.

The encapsulation portion 120 may be to expose one surface of the edge area of the substrate 110 without covering it.

The display panel 100 may have a display surface that displays an image and a rear surface that faces the display surface. The display surface may be defined as the upper surface of the encapsulation portion 120, and the rear surface may be defined as the bottom surface of the substrate 110.

The display surface on which the image is displayed may be parallel (e.g., substantially parallel) to the surface defined by the first direction DR1 and the second direction DR2, and the normal (e.g., substantially perpendicular) direction of the display surface may be the third direction DR3. However, the directions indicated by these directions are relative concepts and may be converted to other directions.

The cover window 200 may overlap the display panel 100. In FIG. 1, the cover window 200 may be on the front of the display panel 100.

The cover window 200 may include a transmissive area TA that may transmit the image provided by the display panel 100, and a non-transmissive area BA around the transmissive area TA. The transmissive area TA may correspond to the display area DA of the display panel 100, and the non-transmissive area BA may correspond to the peripheral area PA of the display panel 100. The non-transmissive area BA may be at the edge area of the cover window 200, and the transmissive area TA may be surrounded by the non-transmissive area BA. The non-transmissive area BA may also be referred to as a light blocking area.

The case member 150 may be at the bottom of the display panel 100 and may accommodate the display panel 100. The case member 150 may be combined with the cover window 200 with the display panel 100 therebetween.

The display device 1000 according to one or more embodiments may further include a flexible printed circuit board 500.

One end of the flexible printed circuit board 500 may be electrically connected to pads on one surface of the substrate 110 exposed by the encapsulation portion 120. The flexible printed circuit board 500 may be bent toward the rear surface of the display panel 100. According to one or more embodiments, the flexible printed circuit board 500 may be electrically connected to pads on the side of the substrate 110. In one or more embodiments, the flexible printed circuit board 500 may not have a portion on one surface of the substrate 110.

The display device 1000 according to one or more embodiments may further include a printed circuit board 600 electrically connected to the other end of the flexible printed circuit board 500.

The printed circuit board 600 may be to output signals to the display panel 100 or receive signals from the display panel 100 through the flexible printed circuit board 500. The other end of the printed circuit board 600 or the flexible printed circuit board 500 may be attached to the lower part of the substrate 110 in a combined state as the flexible printed circuit board 500 is bent.

According to one or more embodiments, the display device 1000 may further include a touch part. The touch part may be between the cover window 200 and the display panel 100. However, embodiments of the present disclosure are not limited thereto, and according to one or more embodiments, the touch part may be inside the display panel 100. Touch parts may be to operate in one or more suitable ways, such as a resistive method, a capacitance method, and/or an electromagnetic induction method, and may be to detect external touches, hovering, and/or the like

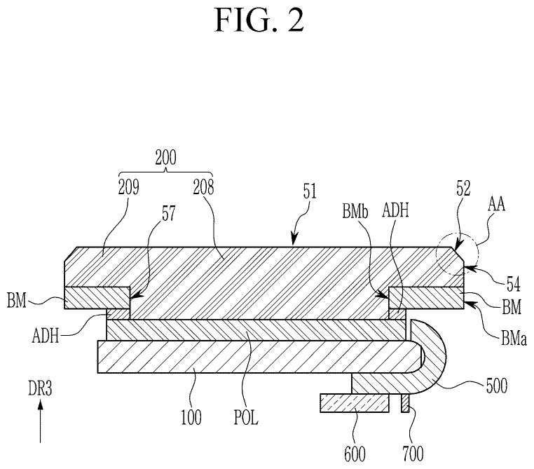

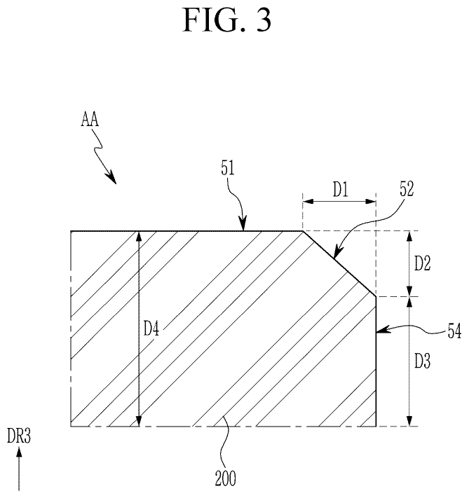

The specific structure of the display device according to one or more embodiments will be described with reference to FIGS. 2-3 along with FIG. 1.

FIG. 2 is a cross-sectional view of a display device according to one or more embodiments. FIG. 3 is a cross-sectional view of a part of an edge of a cover window of a display device as illustrated in FIG. 2.

Referring to FIG. 2, the display device according to one or more embodiments may include a display panel 100, a polarizer POL, a cover window 200, a light blocking film BM, a flexible printed circuit board 500, a printed circuit board 600, and a driver 700. In FIG. 2, the direction stacked in the third direction DR3 is referred to as an upper direction.

In one or more embodiments, the display panel 100 may include a substrate and a plurality of light emitting elements on the substrate. The display panel 100 may include an encapsulation portion that is to cover and protect a plurality of light emitting elements. At least part of the display panel 100 may be flexible and may be transformed into one or more suitable shapes, such as folding (e.g., substantially folding), bending (e.g., substantially bending), and/or rolling (e.g., substantially rolling), or it may be rigid (e.g., substantially rigid) and have a fixed (e.g., substantially fixed) shape.

The polarizer POL may be on the display surface where the display panel 100 is to display the image and may overlap the display panel 100 in the third direction DR3.

The polarizer POL may be to change the characteristics of the light passing through it, such as its phase. For example, the polarizer POL may be to reduce the reflection (e.g., a degree or occurrence of reflection) of the external light incident from the top of the display panel 100. If (e.g., when) the external light passes through the polarizer POL, is reflected by a reflective layer included in the display panel 100, and then passes through the polarizer POL again, the phase of the external light may change. Because the phase of the reflected light and the phase of the external light entering the polarizer POL are substantially different, an extinction interference may occur between the reflected light and the external light. According to one or more embodiments, the polarizer POL may be a circular (e.g., substantially circular) polarizer or an elliptical (e.g., substantially elliptical) polarizer that changes incident light into a circular (e.g., substantially circular) polarization or an elliptical (e.g., substantially elliptical) polarization, and may include at least one phase delay element and a polarizer. According to one or more embodiments, the polarizer POL may be in a form of a film.

An adhesive layer may be between the polarizer POL and the display panel 100. The polarizer POL and the display panel 100 may be in contact with the adhesive layer between them.

The polarizer POL may have an edge that is within the outer edge of the display panel 100 or coincides with the outer edge of the display panel 100. For example, the polarizer POL may overlap the display panel 100 as a whole, and the display panel 100 may have at least some area that does not overlap the polarizer POL and is not covered.

A touch part to detect a touch may further be between the display panel 100 and the polarizer POL, or according to one or more embodiments, the display panel 100 may include a touch part. The touch part may include at least one insulating (e.g., electrically insulating) layer and at least one conductive (e.g., electrically conductive) layer.

The cover window 200 may be on the polarizer POL and may overlap the polarizer POL and the display panel 100 in the third direction DR3. The cover window 200 may include an optically transparent (e.g., substantially transparent) insulating (e.g., electrically insulating) material. For example, the cover window 200 may include resin, which may include a photocurable resin, such as an epoxy resin, a siloxane resin, and/or the like.

The cover window 200 may include a central portion 58 that overlaps the polarizer POL in the third direction DR3 and has an edge that is spaced and/or apart (e.g., spaced apart or separated) from the edge of the polarizer POL on a plane, and an edge portion 59 around the central portion 58. Although they are named or referred to partially depending on the position of the cover window 200, a central portion 208 and an edge portion 209 may be integrally provided.

The thickness of the central portion 208 in the third direction DR3 may be greater than the thickness of the edge portion 209 in the third direction DR3. The entire central portion 208 may overlap the polarizer POL and the display panel 100 in the third direction DR3. The edge portion 209 may include an area that overlaps the polarizer POL in the third direction DR3 and an area that does not overlap the polarizer POL. For example, only the inner part of the edge portion 209 may overlap the polarizer POL in the third direction DR3, and the edge portion 209 may overlap the edge of the polarizer POL in the third direction DR3.

An upper surface 51 of the cover window 200 may be parallel (e.g., substantially parallel) to the display panel 100 except for the edge portion of the edge portion 209. The edge of the upper surface of the edge portion 209 of the cover window 200 may be chamfered. In one or more embodiments, the edge of the upper surface 51 of the cover window 200 may provide an inclined surface 52 that extends in a substantially different direction from the upper surface of the display panel 100. The inclined surface 52 of the cover window 200 may extend in a direction substantially different from each of the first direction DR1, the second direction DR2, and the third direction DR3 and may provide a flat (e.g., substantially flat) surface.

Referring to FIG. 3, the angle by the inclined surface 52 of the edge connected to the upper surface 51 of the cover window 200, which extends in the direction vertical (e.g., substantially vertical) to the third direction DR3, and the third direction DR3 may be about 30° to about 60°, and, for example, about 45°. In the cross-sectional view as illustrated in FIG. 3, lengths of a horizontal width D1 of the inclined surface 52 and a vertical width D2 parallel (e.g., substantially parallel) to the third direction DR3 may be substantially equal to each other. The lengths of the horizontal width D1 and the vertical width D2 of the inclined surface 52 may be, for example, about 70 μm to about 200 μm, respectively.

Referring to FIGS. 2-3, the edge portion 209 of the cover window 200 may have a side surface 54 connected to the inclined surface 52. The side surface 54 may extend in a direction parallel (e.g., substantially parallel) to the third direction DR3 and may have a flat (e.g., substantially flat) surface. Referring to FIG. 3, the sum of the length D3 of the side surface 54 in the third direction DR3 and the vertical width D2 of the cross-section of the inclined surface 52 may be substantially the same as the thickness D4 of the edge portion 209 of the cover window 200 in the third direction DR3. The length D3 of the side surface 54 in the third direction DR3 may be larger than the vertical width D2 of the cross-section of the inclined surface 52. The length D3 of the side surface 54 in the third direction DR3 may be, for example, about 140 μm to about 400 μm.

The thickness of the edge portion 209 of cover window 200 in the third direction DR3 may be less than about 800 μm, and, for example, about 210 μm to about 600 μm.

According to one or more embodiments, the inclined surface 52 of the edge portion 209 of the cover window 200 may include a curved (e.g., substantially curved) surface instead of a flat (e.g., substantially flat) surface.

Referring to FIG. 2, the light blocking film BM may be on the rear surface of the edge portion 209 of the cover window 200 and may overlap the edge portion 209 in the third direction DR3. The light blocking film BM may not overlap the central portion 208 of the cover window 200 in the third direction DR3. The light blocking film BM may be attached to the bottom of the edge portion 209 of the cover window 200 and may be in contact with the bottom of the edge portion 209. A separate adhesive layer may not be between the light blocking film BM and the bottom of the edge portion 209.

The outer edge of the light blocking film BM may be aligned with the outer edge of the cover window 200, for example, the outer edge of the edge portion 209. The outer side BMa of the light blocking film BM may be aligned with the side surface 54 of the edge portion 209 of the cover window 200 and may provide one flat (e.g., substantially flat) surface. The inner side BMb of the light blocking film BM may be in contact with a side surface 57 of the central portion 208 of the cover window 200.

The vertical (e.g., substantially vertical) width on the cross-section of FIG. 2 of the light blocking film BM may be substantially the same as the vertical (e.g., substantially vertical) width on the cross-section of the edge portion 209 of the cover window 200. The width of the light blocking film BM in the third direction DR3 may be less than the width of the edge portion 209 in the third direction DR3 minus the width of the central portion 208 of the cover window 200 in the third direction DR3.

The light blocking film BM may include a material that is to absorb light and may include a material that is to block light. The light blocking film BM may be to block light at the outer edge of the display device by overlapping the edge portion 209 of the cover window 200 on a plane. Referring to FIG. 2, the light blocking film BM may overlap the polarizer POL and the outer edge of the display panel 100 in the third direction DR3. The light blocking film BM may extend outside the edge of the polarizer POL and overlap the edge of the polarizer POL in the third direction DR3.

Referring to FIG. 2, according to one or more embodiments, the display device may further include an adhesive layer ADH between the light blocking film BM and the polarizer POL that overlap each other in the third direction DR3. The adhesive layer ADH may include a pressure-sensitive adhesive (PSA).

The outer edge of the adhesive layer ADH may be aligned with the outer edge of the polarizer POL. The outer side of the adhesive layer ADH may be aligned with the outer side of the polarizer POL and may provide one flat (e.g., substantially flat) surface. The inner side of the adhesive layer ADH may be in contact with the side surface 57 of the central portion 208 of the cover window 200.

The sum of the thickness of the adhesive layer ADH in the third direction DR3, the thickness of the light blocking film BM in the third direction DR3, and the thickness of the edge portion 209 of the cover window 200 in the third direction DR3 may be substantially the same as the thickness of the central portion 208 of the cover window 200 in the third direction DR3.

The thickness of adhesive layer ADH in the third direction DR3 may be about 5 μm or more.

The flexible printed circuit board 500 may include a part on the upper surface of the display panel 100, a part bent around the side of the display panel 100, and a part below the rear surface of the display panel 100. The edge portion of the flexible printed circuit board 500 on the upper surface of the display panel 100 may be spaced and/or apart (e.g., spaced apart or separated) from the polarizer POL. The edge portion of the flexible printed circuit board 500 on the upper surface of display panel 100 may overlap the light blocking film BM in the third direction DR3 and may not be visible if (e.g., when) viewed from the cover window 200 side.

The printed circuit board 600 may be electrically connected to the flexible printed circuit board 500 under the rear surface of the display panel 100.

The driver 700 may be electrically connected to the flexible printed circuit board 500 under the rear surface of the display panel 100. The driver 700 may be mounted on the flexible printed circuit board 500 in a form of a chip on film (COF). The driver 700 may generate a driving signal for the display panel 100.

According to one or more embodiments, because the edge of the upper surface of the cover window 200 of the display device is chamfered to provide the inclined (e.g., substantially inclined) surface, the impact resistance characteristic may be improved or enhanced compared to a shape where the edge of the cover window is sharp (e.g., substantially sharp) or round (e.g., substantially round). For example, as the thickness of the edge portion 209 of the cover window 200 becomes less than about 600 μm, the risk of the edges of the cover window 200 being broken by a dynamic impact may increase, but the cover window 200 of the type or kind according to one or more embodiments may have a reduced risk of being damaged by an impact (e.g., a dynamic impact), and the impact resistance characteristic may be improved or enhanced.

According to one or more embodiments, because the polarizer POL of the display device is within the area where the cover window 200 and the display panel 100 overlap, compared to a structure in which the polarizer extends to the edge of the cover window 200, undesirable defects, such as a discoloration and/or a curling of the polarizer POL, may be prevented (or a degree or occurrence of such defects may be reduced) in high-temperature and/or high-humidity environments. In one or more embodiments, because the polarizer POL is separated from the area where the flexible printed circuit board 500 is attached, issues, such as air bubbles and displacement of conductive (e.g., electrically conductive) adhesives, and/or the like, may be prevented (or a degree or occurrence of such displacement may be reduced), compared to a structure that overlaps the flexible printed circuit board.

According to one or more embodiments, because the light blocking film BM of the display device is attached to the polarizer POL through the adhesive layer ADH in the form of a separate film, compared to a structure that forms a light blocking material directly on the polarizer or the cover window through inkjet or printing methods, undesirable defects caused by the light blocking materials that may occur in high-temperature and/or high-humidity environments may be prevented (or a degree or occurrence of such defects may be reduced).

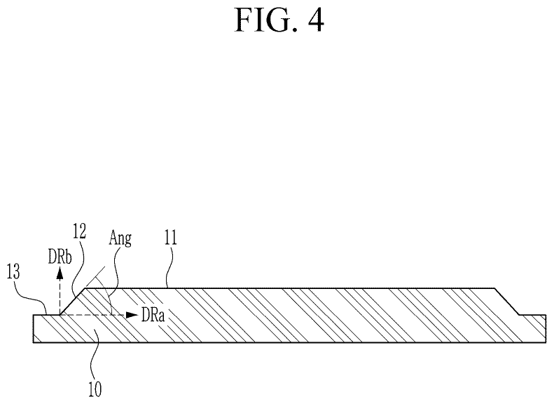

The manufacturing method of the display device according to one or more embodiments is illustrated with reference to FIGS. 4-16 along with the other drawings as described in one or more embodiments. The manufacturing method of the display device as described in one or more embodiments may include the manufacturing method of the cover window for the display device.

FIG. 4 is a cross-sectional view of a master mold in one process step of a manufacturing method of a display device according to one or more embodiments.

Referring to FIG. 4, a master mold 10 including glass and/or metal may be provided. The upper surface of the master mold 10 may include a center upper surface 11 that is in the center and extends in a direction DRa parallel (e.g., substantially parallel) to the bottom surface of the master mold 10, an inclined surface 12 that is connected to the edge of the center upper surface 11, and an edge of the upper surface 13 that is connected to the edge of the inclined surface 12 and extends in the direction DRa parallel (e.g., substantially parallel) to the bottom surface of the master mold 10. The inclined surface 12 may extend in a direction other than the direction DRa and a direction DRb perpendicular (e.g., substantially perpendicular) to the direction DRa. The angle Ang by the inclined surface 12 by the direction DRa may be determined according to the inclined (e.g., substantially inclined) direction and/or the inclined (e.g., substantially inclined) angle of the inclined surface 52 of the cover window 50 as described in one or more embodiments, and may be, for example, about 45°. The center upper surface 11, the inclined surface 12, and the edge upper surface 13 may each have a flat (e.g., substantially flat) surface.

The master mold 10 may be provided through a polishing process and/or a chamfering process, and the upper surface of the master mold 10 may not be fluorine treated. In one or more embodiments, the planarity of the surface may be maintained by suppressing or preventing the reaction (e.g., chemical reaction) (or by reducing a degree or occurrence of the reaction) between the material to be provided later on the master mold 10 and the upper surface of the master mold 10. If (e.g., when) the master mold 10 includes a metal, the upper surface of the master mold 10 may be processed with a diamond turning machine (DTM) so that surface roughness may increase or enhance.

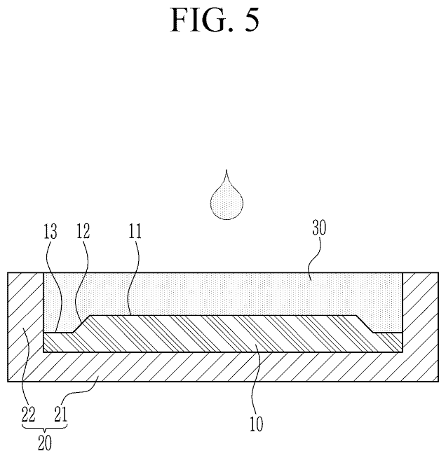

FIG. 5 is a view illustrating an intermediate step to provide a mold by using a master mold in one process step of a manufacturing method of a display device according to one or more embodiments.

Referring to FIG. 5, after installing the master mold 10 into a frame 20, a mold material may be coated or applied on the master mold 10. The mold material may include a plastic resin and, for example, a polymer organic material, such as polydimethylsiloxane (PDMS). The frame 20 may include a base 21 and a dam 22 providing a side portion at the edge of the base 21. The dam 22 may define the area where the material for the mold is to be provided. The frame 20 may include a material that may be later be relatively easily removed from the master mold 10, for example, silicon.

Application of the mold material may be performed using inkjet printing.

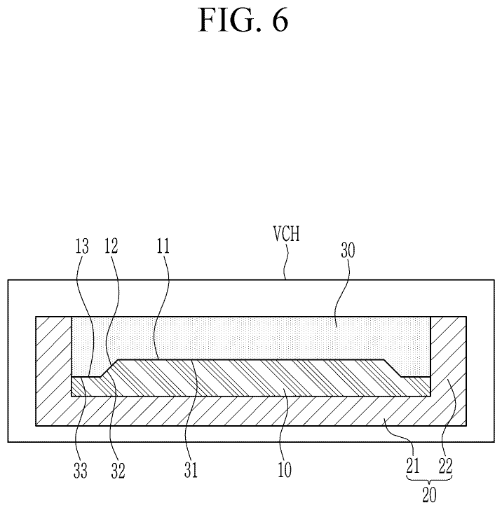

FIG. 6 illustrates the processing of a mold in a vacuum chamber in the intermediate step as illustrated in FIG. 5.

Referring to FIG. 6, the shape of the mold 30 provided by the coating of the mold material at the boundary with the master mold 10 may be provided according to the shape of the master mold 10. The mold 30 may have a center upper surface 31 in contact with the center upper surface 11 of the master mold 10, an inclined surface 32 in contact with the inclined surface 12 of the master mold 10, and an edge upper surface 33 in contact with the edge upper surface 13 of the master mold 10. In FIG. 6, the center upper surface 31 and the edge upper surface 33 of the mold 30 are illustrated as the lower surface, but may be later named or referred to as the upper surface for better understanding and ease of description.

By placing the master mold 10 and the frame 20, in which the mold 30 is provided, into a vacuum chamber (VCH), the strength of the mold 30 may be optimized or increased, thereby increasing or enhancing modularity, tensile strength, and tear strength. The atmospheric pressure within the vacuum chamber (VCH) may be, for example, about 10 Pa or less. In the vacuum chamber (VCH), air bubbles in the mold may be removed, and an oxidation reaction of hydrophobic PDMS may be controlled.

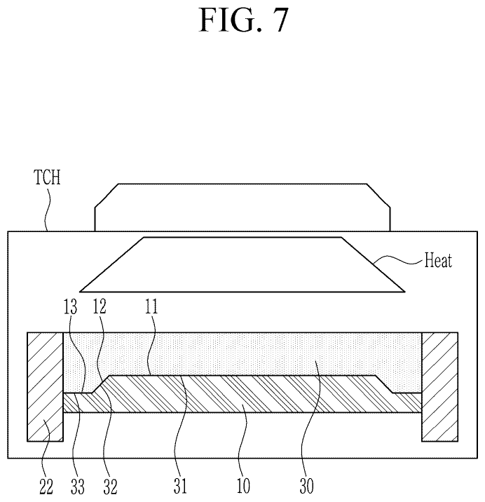

FIG. 7 is a view illustrating a step to cure a mold by heat treatment (e.g., heat curing) after a processing step as illustrated in FIG. 6.

Referring to FIGS. 6-7, the master mold 10 and the frame 20 in which the mold 30 is provided may be heat cured in a thermal chamber (TCH). Through this process, the modulus and the strength of the mold 30 may be increased or enhanced. The temperature within the thermal chamber (TCH) may be, for example, about 60° C. to about 80° C. Through this low-temperature heat curing, the shrinkage of the mold may be minimized (or a degree or occurrence of the shrinkage of the mold 30 may be reduced) to within about 0.5%. The modularity of the mold 30, which may be deteriorated by low-temperature heat curing, may be controlled by increasing the ratio of the base polymer contained in the mold 30. After heat curing in a thermal chamber (TCH), the base 21 of the frame 20 may be removed. The dam 22 of the frame 20 may be left behind.

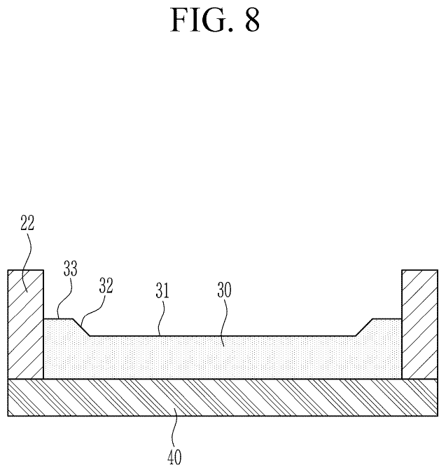

FIG. 8 is a view illustrating a step to attach a mold to a substrate after the thermal curing step as illustrated in FIG. 7.

Referring to FIGS. 7-8, after heat curing, the master mold 10 may be removed from the mold 30, and the dam 22 of the frame 20 and the mold 30 may be turned over and attached to the substrate 40. The substrate 40 may include a material having relatively high transmittance, such as transparent (e.g., substantially transparent) glass. The substrate 40 may prevent or reduce the deformation (or a degree or occurrence of the deformation) of the mold 30 if (e.g., when) coating the material for the cover window in a later step. The surfaces of the center upper surface 31, the inclined surface 32, and the edge upper surface 33 of the exposed upper surface of the mold 30, may be treated with fluorine to increase or enhance surface energy. Therefore, low adherence to the material for the cover window coated in a subsequent step may be maintained.

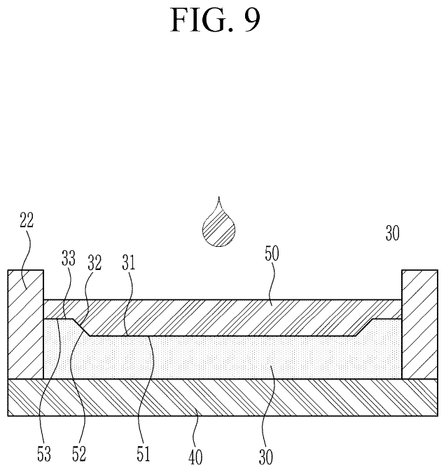

FIG. 9 is a view illustrating the step to coat (e.g., to apply) a material for a cover window on a mold as illustrated in FIG. 8.

Referring to FIG. 9, the material for the cover window, for example, resin, may be coated or applied on the upper surface of the mold 30. The coating method may be performed by inkjet printing. The shape of the boundary between the cover window 50, which is provided by coating the material for the cover window, and the mold 30 may be provided according to the shape of the mold 30. In one or more embodiments, the cover window 50 may be substantially different from a completed cover window 200 as described in one or more embodiments and may be the cover window before curing and cutting. The cover window 50 may be referred to as a pre-curing cover window.

The cover window 50 may have an upper surface 51 in contact with the center upper surface 31 of the mold 30, an inclined surface 52 in contact with the inclined surface 32 of the mold 30, and an edge upper surface 53 in contact with the edge upper surface 13 of the mold 30. In FIG. 9, the upper surface 51 and the edge upper surface 53 of the cover window 50 are illustrated as the lower surface, but may be referred to as the upper surface for better understanding and ease of description and consistency with the foregoing description.

After providing the cover window 50 on the mold 30 and after waiting a set or predetermined time, it may be provided in a vacuum chamber to further defoam.

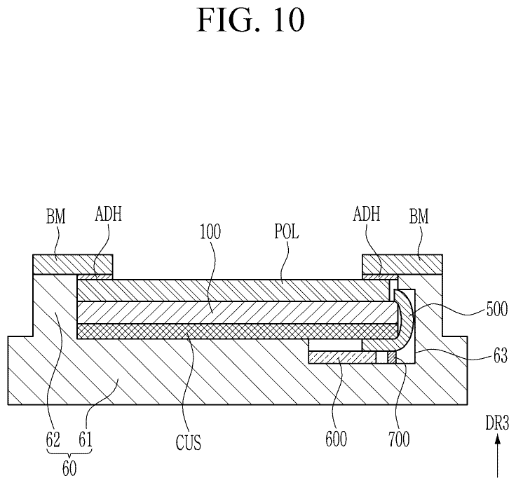

FIG. 10 is a view representing a step to mount a display panel, a polarizer, and a light blocking film on a jig according to one or more embodiments.

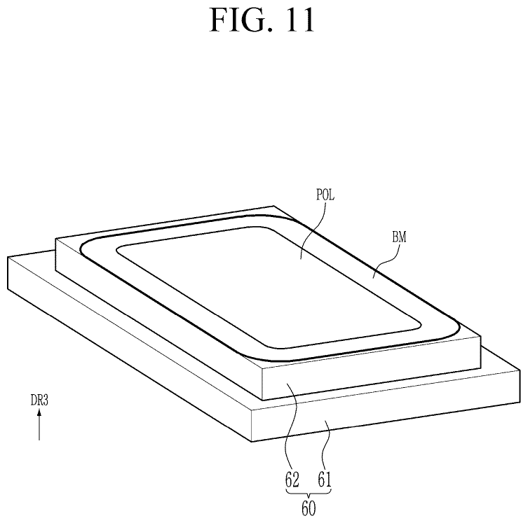

FIG. 11 is a perspective view of a state in which a polarizer and a light blocking film are mounted on a jig in the step as illustrated in FIG. 10.

Referring to FIGS. 10-11, the polarizer POL and the display panel 100 bonded thereto may be mounted on a supporting portion 61 of a jig 60 including the supporting portion 61 that extends in the direction vertical (e.g., substantially vertical) to the third direction DR3 and a side portion 62 protruded from the supporting portion 61 in the third direction DR3. The jig 60 may have vacuum adsorption holes on the upper surface of the supporting portion 61 and the upper surface of the side portion 62 to enable vacuum adsorption of objects mounted thereon.

A protective member CUS may be at the lower part of the display panel 100 and may be mounted on the supporting portion 61 of the jig 60 along with the display panel 100. The protective member CUS may include at least one selected from among an acryl-based compound, a polymeric resin, such as polyethylene terephthalate (PET), polyimide (PI), and/or the like, and a metal, such as copper. The protective member CUS may be to perform functions, such as light blocking, heat dissipation, and/or impact absorption, for the display panel 100. The protective member CUS may be between the supporting portion 61 of the jig 60 and the display panel 100. According to one or more embodiments, the protective member CUS may be omitted or included in the display panel 100.

The display panel 100 and the polarizer POL may be mounted within the area surrounded by the side portion 62 of the jig 60. The flexible printed circuit board 500, the printed circuit board 600, and the driver 700 connected to the display panel 100 may also be mounted on the jig 60. The flexible printed circuit board 500, the printed circuit board 600, and the driver 700 on the rear surface of the display panel 100 may be in a recess portion 63 on a part of the upper surface of the supporting portion 61 of the jig 60.

After mounting the display panel 100 and the polarizer POL on the jig 60, the adhesive layer ADH may be provided on the area where the light blocking film BM is to be attached among the edge areas of the polarizer POL. Next, the light blocking film BM may be attached over the adhesive layer ADH on the upper surface of the side portion 62 of the jig 60 and the edge area of the polarizer POL adjacent to the side portion 62. The light blocking film BM may be attached to the polarizer POL through the adhesive layer ADH. The light blocking film BM may overlap the boundary between the polarizer POL and the side portion 62 of the jig 60. The light blocking film BM may be along the edge of the polarizer POL on a plane to provide a closed curved (e.g., substantially curved) line.

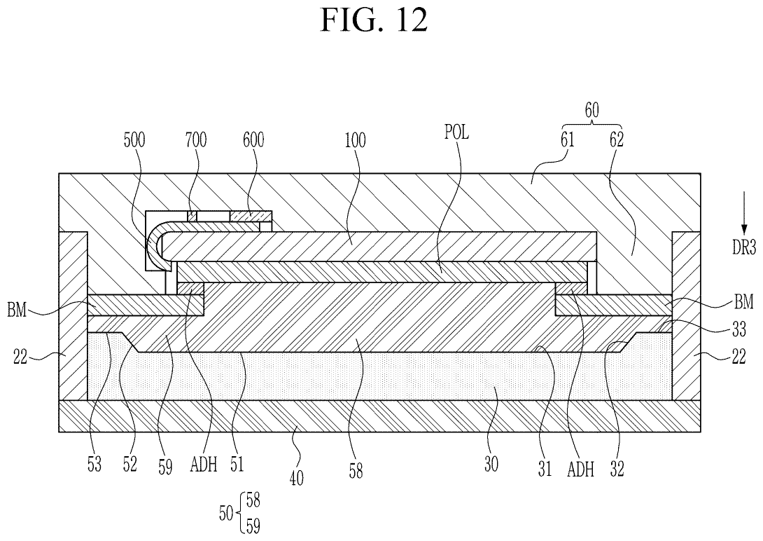

FIG. 12 is a view illustrating a combination of a jig as illustrated in FIGS. 10-11 over the cover window material applied in the step as illustrated in FIG. 9.

Referring to FIG. 12, a vacuum state of the inside of the jig 60 may be provided, and the display panel 100 and the light blocking film BM may be fixed to the jig 60 through vacuum adsorption. In FIG. 12, the illustration of the protective member CUS is omitted.

The jig 60 may be aligned to the dam 22 and the mold 30 of the frame as illustrated in FIG. 9, and they may be cemented on the cover window 50. Having the cover window 50 bonded with the light blocking film BM and the polarizer POL, the side portion 62 of the jig 60 may enter the area surrounded by the dam 22, and the outer side of the side portion 62 and the inner side of the dam 22 may be in contact. The light blocking film BM may be bonded by coming into contact with the upper surface of the edge area of the cover window 50. The edge area of the cover window 50 pressed by the side portion 62 of the jig 60 and the light blocking film BM may become less thick, and the central area may be left relatively thick. In one or more embodiments, the central portion 58 and the edge portion 59 of the cover window 50 may be provided. In one or more embodiments, the central portion 58 and the edge portion 59 may be substantially distinguished from the central portion 208 and the edge portion 209 of the completed cover window 200 as described in one or more embodiments, and may be the central portion and the edge portion before curing and cutting of the cover window. The central portion 58 of the cover window 50 may be in contact with the polarizer POL and may be cemented.

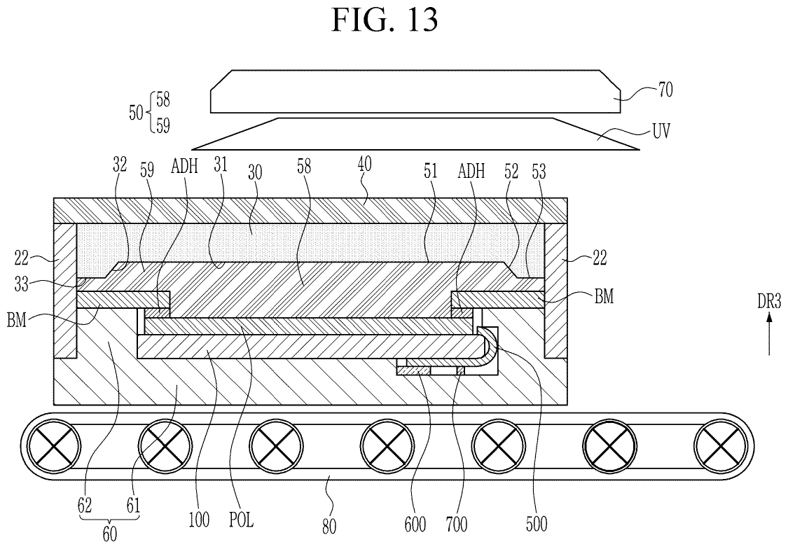

FIG. 13 is a view illustrating a step to cure a material for a cover window after the step as illustrated in FIG. 12,

Referring to FIG. 13, the cover window 50 may be cured by irradiating UV light with a UV lamp 70 to the jig 60 and the mold 30 cemented in FIG. 12. A metal halide UV lamp may be used as the UV lamp 70. In order to evenly (e.g., substantially evenly) cure the cover window 50, the cemented jig 60 and mold 30 may be provided on a conveyor 80 and moved. The substrate 40 and the mold 30 on which the mold 30 is provided may have a UV transmittance of substantially equal to or more than about 90%.

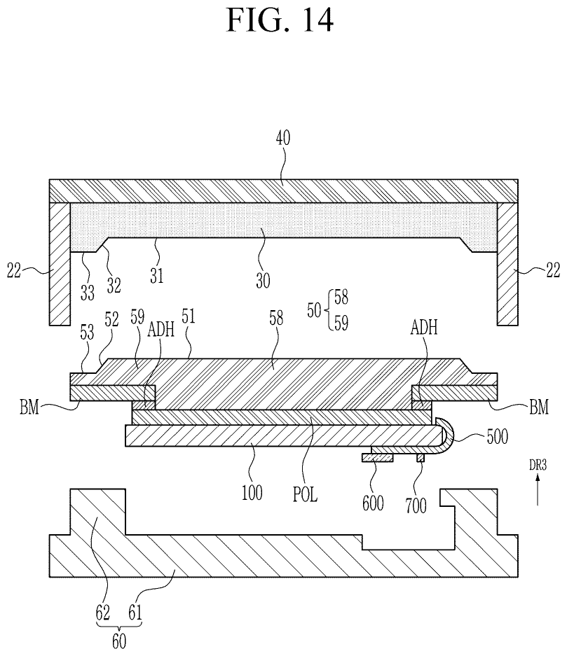

FIG. 14 is a view illustrating a step to remove a mold and a jig after the step as illustrated in FIG. 13.

Referring to FIG. 14, the substrate 40, the mold 30, and the dam 22 may be removed from the hardened cover window 50, and the jig 60 may also be removed. At this time, as described in one or more embodiments, due to the relatively low contact force of the contact surface of the mold 30 with the cover window 50, the cover window 50 may be relatively easily separated while maintaining high surface quality. The cover window 50 may have the upper surface 51, the inclined surface 52, and the edge upper surface 53.

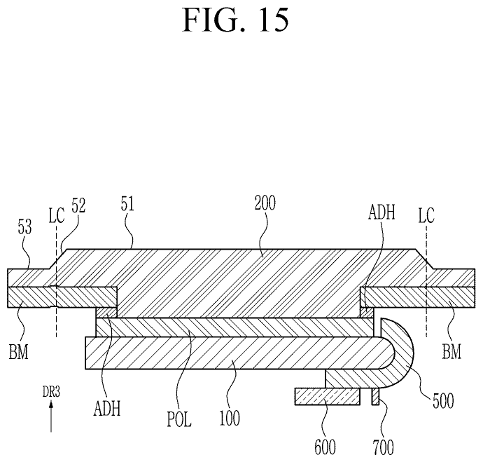

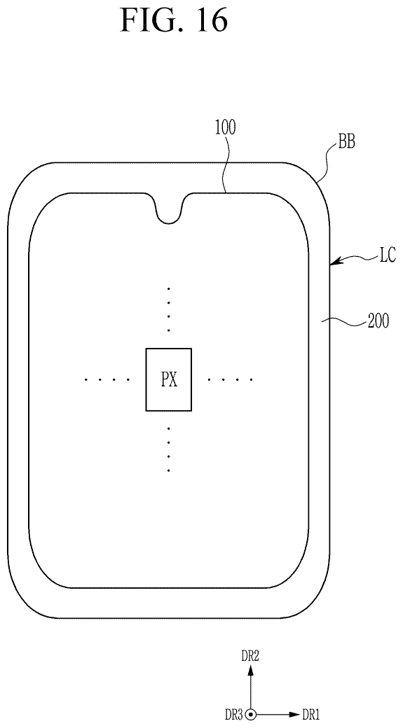

FIG. 15 is a view illustrating a step to cut a cover window, and FIG. 16 is a top plan view of a cover window cut in the step as illustrated in FIG. 15.

Referring to FIG. 15, the cover window 50 may be cut in the third direction DR3 along a cutting line LC that overlaps the inclined surface 52 of the cover window 50 to provide the completed cover window 200. The position of the cutting line LC may vary depending on conditions, such as the inclination angle and length of the inclined surface 52. Laser cutting may be used to cut the cover window 50. If (e.g., when) the cover window 50 is cut, the light blocking film BM may also be cut so that the outer side portion of the light blocking film BM may be removed. The cutting line LC may not overlap the polarizer POL and the display panel 100.

Referring to FIG. 16, in a plan view, the edge of the cover window 200 at the cutting line LC for the cover window 50 may have a shape parallel (e.g., substantially parallel) to the edge of the display panel 100, and the edge BB of the cover window 200 may have a rounded (e.g., substantially rounded) shape. However, the planar shape of the display panel 100 and the cover window 200 is not limited to what is illustrated in one or more embodiments.

According to the manufacturing method of the display device according to one or more embodiments, because no separate adhesive is used between the cover window 200 and the polarizer POL, the manufacturing cost of the display device may be reduced, the defect rate according to the process may be reduced, and the thickness and weight of the display device may also be reduced. In one or more embodiments, because the polarizer POL has a narrower area than the cover window 200, undesirable defects, such as discoloration and bending of the polarizer may be prevented (or a degree or occurrence of such defects may be reduced), and the cover window 200 may be further flat.

According to one or more embodiments, the master mold 10 may include a curved (e.g., substantially curved) surface instead of the inclined surface 12, the mold 30 as described in one or more embodiments may also include a curved (e.g., substantially curved) surface instead of the inclined surface 32, and the cover window 200 as described in one or more embodiments may also include a curved (e.g., substantially curved) surface instead of the inclined surface 52. The inclined surface 12 or the curved surface of the master mold 10 may be referred to as an inclined surface, the inclined surface 32 or the curved surface of the mold 30 may be referred to as an inclined surface, and the inclined surface 52 or the curved surface of cover window 200 may be referred to as an inclined surface.

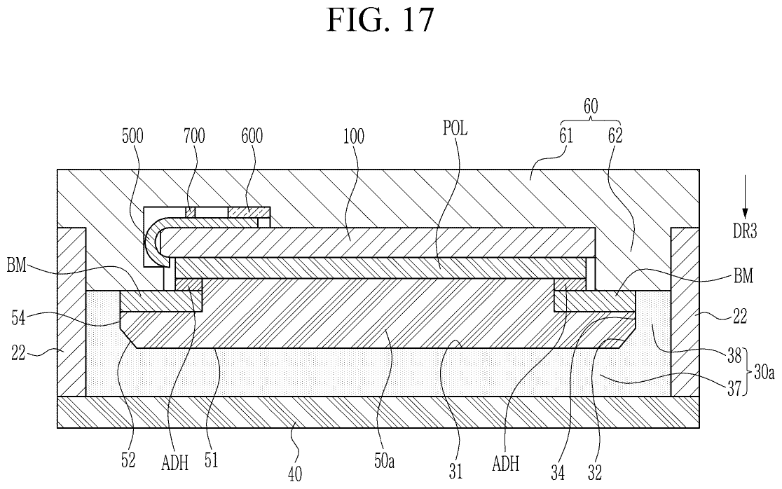

FIG. 17 is a view illustrating a combination of a jig in which a display panel, a polarizer, and a light blocking film are mounted on a material for a cover window coated on a mold in one process step of a manufacturing method of a display device according to one or more embodiments,

Referring to FIG. 17, the manufacturing method of the display device according to one or more embodiments may be substantially the same as the manufacturing method of the display device as illustrated in FIGS. 4-16, but the shape of the mold 30a may be slightly different, and the cutting process for the cover window 50 and the light blocking film BM as illustrated in FIG. 15 may be omitted.

In one or more embodiments, the mold 30a according to one or more embodiments may have a bottom portion 37 that is on the substrate 40 and extends in the elongation direction of the surface of the substrate 40, for example, the direction vertical (e.g., substantially vertical) to the third direction DR3, and a vertical portion 38 that is connected to the bottom portion 37 and extends in the third direction DR3. The bottom portion 37 may have a center upper surface 31 like the mold 30 as described in one or more embodiments, and the vertical portion 38 may have a vertical surface 34 to provide an inner side surface. According to one or more embodiments, the mold 30a may have an inclined surface 32 between the center upper surface 31 and the vertical surface 34 as described in one or more embodiments. According to one or more embodiments, the mold 30a may not have the edge upper surface 33 as described in one or more embodiments. The vertical surface 34 may have the surface parallel (e.g., substantially parallel) to the direction vertical (e.g., substantially vertical) to the center upper surface 31, for example, the third direction DR3.

The vertical portion 38 may be in contact with the inner surface of the dam 22 used if (e.g., when) the mold 30a is provided.

On the upper surface of the mold 30a according to one or more embodiments as illustrated in FIG. 17, the shape of the cover window 50a provided by coating the material for the cover window on the boundary with the mold 30a may be provided according to the shape of the mold 30a. The cover window 50a may have an upper surface 51 in contact with the center upper surface 31 of the mold 30a, the inclined surface 52 in contact with the inclined surface 32 of the mold 30a, and the side surface 54 in contact with the vertical surface 34 of the vertical portion 38 of the mold 30a. The side surface 54 may be aligned with the side of the light blocking film BM to provide one flat (e.g., substantially flat) surface. The shape of the cover window 50a on the mold 30a may be substantially identical to the shape of the cover window 200 as illustrated in FIG. 2.

As illustrated in FIG. 17, after aligning and attaching the jig 60 to the dam 22 of the frame and the mold 30a, then hardening the cover window 50a, if (e.g., when) the substrate 40, the mold 30a, the dam 22, and the jig 60 are removed, the cover window 200 according to one or more embodiments may be provided without the cutting the cover window as illustrated in FIG. 15.

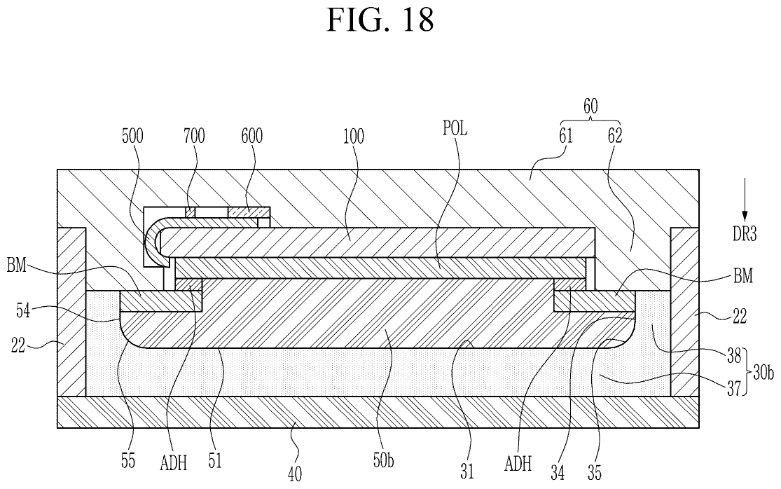

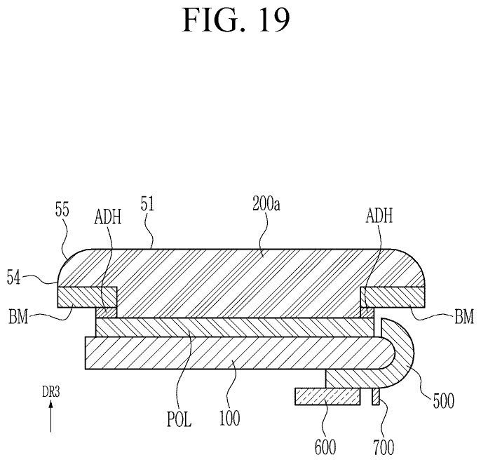

FIG. 18 is a view illustrating a combination of a jig in which a display panel, a polarizer, and a light blocking film are mounted on a material for a cover window coated or provided on a mold in one process step of a manufacturing method of a display device according to one or more embodiments, and FIG. 19 is a cross-sectional view of a display device according to one or more embodiments.

Referring to FIG. 18, the manufacturing method of the display device according to one or more embodiments may be substantially the same as the manufacturing method of the display device as illustrated in FIG. 17, but the shape of the mold 30b may be partially different.

For example, the mold 30b according to one or more embodiments may be mostly identical (or substantially identical) to the mold 30a as illustrated in FIG. 17, but the inclined (e.g., substantially inclined) surface between the center upper surface 31 and the vertical surface 34 may be a curved surface 35 instead of an inclined (e.g., substantially inclined) surface.

The shape of the cover window 50b provided by coating or applying the material for the cover window on the upper surface of the mold 30b as illustrated in FIG. 18 at the boundary with the mold 30b may be provided according to the shape of the mold 30b. The cover window 50b may have the upper surface 51 in contact with the center upper surface 31 of the mold 30b, the curved surface 55 in contact with the curved surface 35 of the mold 30b, and a side surface 54 in contact with the vertical surface 34 of the vertical portion 38 of the mold 30b.

After aligning and bonding the jig 60 to the dam 22 of the frame and the mold 30b, as illustrated in FIG. 18, curing the cover window 50b, and then removing the substrate 40, the mold 30b, the dam 22, and the jig 60, the cover window 200a as illustrated in FIG. 19 may be provided.

Referring to FIG. 19, the display device including the cover window 200a according to one or more embodiments may be largely identical (or substantially identical) to the display device including the cover window 200 as illustrated in FIG. 2, but the upper surface of the cover window 200a may have the curved surface 55 at the edge instead of the inclined surface 52.

In the manufacturing method of the display device as illustrated in FIG. 18, the cover window 200a according to one or more embodiments may be provided without cutting the cover window as illustrated in FIG. 15.

One or more embodiments of the present disclosure provide an electronic device including the display device as described in one or more embodiments.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

While the subject matter of the present disclosure has been described in connection with what is presently considered to be practical embodiments, it should be understood that the present disclosure is not limited to the disclosed embodiments, but, in one or more embodiments, is intended to cover one or more suitable modifications and equivalent arrangements included within the spirit and scope of the appended claims and equivalents thereof. It therefore will be understood that one or more embodiments described above are just illustrative but not limitative in all aspects.

### REFERENCE NUMERALS

| | |
|---|---|
| 10: master mold | 11, 31: center upper surface |
| 12, 32, 52: inclined surface | 13, 33, 53: edge upper surface |
| 20: frame | 21: base |
| 22: dam | 30, 30a, 30b: mold |
| 34: vertical surface | 35, 55: curved surface |
| 37: bottom portion | 38: vertical portion |
| 40, 110: substrate | 50, 50a, 50b, 200, 200a: cover |
| | window |
| 51: upper surface | 54, 57: side surface |
| 58, 208: central portion | 59, 209: edge portion |
| 60: jig | 61: supporting portion |
| 62: side portion | 63: recess portion |
| 70: UV lamp | 100: display panel |
| 120: encapsulation portion | 150: case member |
| 500: flexible printed circuit board | 600: printed circuit board |
| 700: driver | 1000: display device |
| ADH: adhesive layer | BM: light blocking film |
| POL: polarizer | |

What is claimed is:

1. A display device, comprising:
a display panel comprising a plurality of pixels,
a polarizer on the display panel,
a cover window on the polarizer,
a light blocking film on a rear surface of the cover window, and
an adhesive layer between the light blocking film and the polarizer,
wherein the adhesive layer is only between the light blocking film and the polarizer which overlap each other.

2. The display device as claimed in claim 1, wherein:
the cover window comprises:
a central portion that overlaps the polarizer, and
an edge portion around the central portion, and
a thickness of the central portion in a first direction is greater than a thickness of the edge portion in the first direction.

3. The display device as claimed in claim 2, wherein:
the edge portion comprises an area that overlaps the polarizer in the first direction and an area that does not overlap the polarizer in the first direction, and
the light blocking film is in contact with a rear surface of the edge portion and does not overlap the central portion in the first direction.

4. The display device as claimed in claim 3, wherein:
an inner side of the light blocking film is in contact with a side of the central portion,
an outer side of the light blocking film is aligned with a side of the edge portion, and
an inner side of the adhesive layer is in contact with a side of the central portion.

5. The display device as claimed in claim 4, wherein:
a sum of a thickness of the adhesive layer, a thickness of the light blocking film, and a thickness of the edge portion in the first direction is equal to a thickness of the central portion in the first direction.

6. The display device as claimed in claim 2, wherein:
the central portion is in contact with the polarizer.

7. The display device as claimed in claim 2, wherein:
an edge of an upper surface of the edge portion is chamfered to provide an inclined surface.

8. A display device, comprising:
a display panel comprising a plurality of pixels,
a polarizer on the display panel,
a cover window on the polarizer,
a light blocking film on a rear surface of the cover window, and
an adhesive layer between the light blocking film and the polarizer,
wherein the cover window comprises:
a central portion that overlaps the polarizer, and
an edge portion around the central portion,
the central portion is in contact with the polarizer,
the edge portion is not in contact with the polarizer, and
the adhesive layer is between the edge portion and the polarizer.

9. The display device as claimed in claim 8, wherein:
a thickness of the central portion in a first direction is greater than a thickness of the edge portion in the first direction.

10. The display device as claimed in claim 9, wherein:
the edge portion comprises an area that overlaps the polarizer in the first direction and an area that does not overlap the polarizer in the first direction.

11. The display device as claimed in claim 10, wherein:
the light blocking film is in contact with a rear surface of the edge portion and does not overlap the central portion in the first direction.

12. The display device as claimed in claim 11, wherein:
an inner side of the light blocking film is in contact with a side of the central portion,
an outer side of the light blocking film is aligned with a side of the edge portion, and
an inner side of the adhesive layer is in contact with a side of the central portion.

13. The display device as claimed in claim 12, wherein:
a sum of a thickness of the adhesive layer, a thickness of the light blocking film, and a thickness of the edge portion in the first direction is equal to a thickness of the central portion in the first direction.

14. The display device as claimed in claim 8, wherein:
an edge of an upper surface of the edge portion is chamfered to provide an inclined surface.

15. A manufacturing method of a display device, comprising:
preparing a mold having a first upper surface and a first inclined surface connected to the first upper surface,
coating a material for a cover window on the mold to provide a first cover window having a second upper surface in contact with the first upper surface and a second inclined surface in contact with the first inclined surface,
mounting a display panel and a polarizer joined to each other on a supporting portion of a jig comprising the supporting portion and a side portion;
providing an adhesive layer in an edge area of the polarizer;
attaching a light blocking film on and across an upper surface of the side portion of the jig and the adhesive layer; and
bonding the polarizer and the light blocking film fixed to the jig on the first cover window to provide a second cover window comprising an edge portion in contact with the light blocking film and a central portion in contact with the polarizer.

16. The manufacturing method of the display device as claimed in claim 15, wherein:
a thickness of the central portion in a first direction is greater than a thickness of the edge portion in the first direction.

17. The manufacturing method of the display device as claimed in claim 16, wherein:
the second cover window has the second upper surface and the second inclined surface, and
the method further comprising:
curing the second cover window;
removing the mold and the jig, and
cutting the second cover window and the light blocking film along a cutting line that overlaps the second inclined surface.

18. The manufacturing method of the display device as claimed in claim 17, wherein:
the mold further has a first edge upper surface that is connected to the first inclined surface and is parallel to the first upper surface,
the first cover window further has a second edge upper surface that is connected to the second inclined surface and is parallel to the second upper surface, and
the inclined surface is a flat surface.

19. The manufacturing method of the display device as claimed in claim 16, wherein:
the mold has a vertical surface that is connected to the first inclined surface and is vertical to the first upper surface,
the first cover window has a side that is connected to the second inclined surface and is perpendicular to the second upper surface, and
a side of the light blocking film is aligned with the side of the first cover window.

20. An electronic device, comprising:
a display device comprising:
a display panel comprising a plurality of pixels,
a polarizer on the display panel,
a cover window on the polarizer,
a light blocking film on a rear surface of the cover window, and
an adhesive layer between the light blocking film and the polarizer,
wherein the adhesive layer is only between the light blocking film and the polarizer which overlap each other.
